(19) United States
(12) Patent Application Publication
(10) Pub. No.: US 2010/0248417 A1
(43) Pub. Date: Sep. 30, 2010

(54) METHOD FOR PRODUCING CHALCOPYRITE-TYPE SOLAR CELL

(75) Inventors: Satoshi Yonezawa, Utsunomiya-shi (JP); Yoshinori Tokunaga, Utsunomiya-shi (JP); Tetsuya Sugano, Utsunomiya-shi (JP)

Correspondence Address: ARENT FOX LLP, 1050 CONNECTICUT AVENUE, N.W., SUITE 400, WASHINGTON, DC, 20036, US

(73) Assignee: HONDA MOTOR CO., LTD., Tokyo (JP)

(21) Appl. No.: 12/748,348

(22) Filed: Mar. 26, 2010

(30) Foreign Application Priority Data
Mar. 30, 2009 (JP) 2009-081327

(51) Int. Cl. H01L 31/0272

(52) U.S. Cl. 438/84; 257/E31.008

(57) ABSTRACT

The present invention relates to a method for producing a chalcopyrite-type solar cell. The chalcopyrite-type solar cell has a light absorbing layer formed by selenizing a Cu—In—Ga alloy layer. The alloy layer is formed on a first electrode layer by sputtering using only a Cu—In—Ga alloy target (CIG target).

### CROSS-REFERENCE TO RELATED APPLICATION

This application is based upon and claims the benefit of priority from Japanese Patent Application No. 2009-081327 filed on Mar. 30, 2009, of which the contents are incorporated herein by reference.

### BACKGROUND OF THE INVENTION

1. Field of the Invention

The present invention relates to a method for producing a chalcopyrite-type solar cell having a light absorbing layer containing a chalcopyrite-type compound.

2. Description of the Related Art

A chalcopyrite-type solar cell has a light absorbing layer containing a chalcopyrite-type compound such as Cu(In,Ga)Se (so-called CIGS), and shows excellent properties such as a conversion efficiency higher than those of silicon solar cells. For example, this chalcopyrite-type solar cell has a stack structure containing a glass substrate, a first electrode layer formed on the substrate, the light absorbing layer containing a p-type semiconductor of the chalcopyrite-type compound such as the Cu(In,Ga)Se, a buffer layer containing an n-type semiconductor, and a transparent second electrode layer stacked in this order.

In the stack structure, the light absorbing layer may be formed by the steps of multi-sputtering Cu, In, and Ga targets in no particular order, thereby stacking a Cu layer 2, an In layer 3, and a Ga layer 4 on a first electrode layer 1 as shown in FIG. 9 to prepare a precursor, and then subjecting the Cu layer 2, In layer 3, and Ga layer 4 to a heat treatment in a selenization atmosphere, thereby alloying and selenizing the Cu, In, and Ga. The precursor may be prepared by multi-sputtering a Cu—Ga alloy target and an In target in no particular order as disclosed in Japanese Laid-Open Patent Publication No. 10-135495.

In the above technologies, the two steps of the multiple sputtering and the selenization treatment must be carried out, so that it takes a long time to form the light absorbing layer. In view of the problem, technologies for forming the light absorbing layer without the selenization treatment, which contains sputtering using a chalcopyrite-type compound semiconductor target, are proposed in Japanese Laid-Open Patent Publication Nos. 08-172052 and 2008-163367.

### SUMMARY OF THE INVENTION

The present inventors have confirmed that when the light absorbing layer is formed by the steps of forming the elements other than Se into the three or two layered precursor and subjecting the prepared precursor to the selenization treatment as described above, Ga is selectively segregated on the first electrode layer 1. This is because Ga and In have different reactivities with Se and show different thermal diffusion rates in the film during the production of the CIGS compound. As a result of intense research, the inventors have found that as shown in FIG. 10, thus obtained light absorbing layer 5 has a bilayer structure containing a CuGaSe₂ layer 6 and a Cu(In,Ga)Se layer 7 due to the Ga segregation. In other words, the crystal layers having different compositions are stacked in the light absorbing layer 5. When the light absorbing layer 5 has such a separate bilayer structure, the resultant chalcopyrite-type solar cell has a lowered conversion efficiency.

It is common knowledge that the ideal bandgap of the solar cell is 1.4 eV at an air mass (AM) of 1.5, and that if Ga/(In+Ga)=0.6, then the Ga concentration is ideal for obtaining the bandgap of 1.4 eV in the light absorbing CIGS layer. When the above precursor having the three or two layer structure is subjected to the selenization treatment such that the ideal Ga concentration is obtained, the Ga segregation is further accelerated due to the high Ga concentration, whereby the separation of the light absorbing layer into the bilayer structure becomes more significant to lower the conversion efficiency.

This problem is caused even in the case of changing the sputtering order of the Cu, In, and Ga. Thus, this problem cannot be solved only by forming the Ga layer at the end of the multi-sputtering. In fact, in the method for forming the precursor (i.e. the method for producing the chalcopyrite-type solar cell) according to the above conventional technologies, when the Ga concentration is increased in order to obtain the Ga/Group III ratio of 0.6, Ga is segregated in the bottom of the light absorbing layer, whereby the high Ga composition ratio cannot be obtained in the resultant CIGS, and the above separation into the bilayer structure is caused, thereby lowering the conversion efficiency.

In the case of using an Se-containing target as described in Japanese Laid-Open Patent Publication Nos. 08-172052 and 2008-163367, the elements show different plasma sputtering rates, whereby the Se composition ratio of the resultant CIGS layer is disadvantageously lower than that of the target. In other words, the light absorbing layer has a low Se content, and thereby cannot have a desired composition. Therefore, in this case, it is necessary to add Se to the light absorbing layer.

Furthermore, the Se-containing target has a high resistance and must be sputtered by RF sputtering or the like. However, the RF sputtering disadvantageously has a low film formation speed. In the RF sputtering, it takes a longer time to form the light absorbing layer, whereby the production efficiency of the chalcopyrite-type solar cell is deteriorated.

A general object of the present invention is to provide a method for producing a chalcopyrite-type solar cell having a light absorbing layer containing a chalcopyrite-type compound, capable of preventing separation of the light absorbing layer.

A principal object of the present invention is to provide a method for producing a chalcopyrite-type solar cell having a light absorbing layer with an improved film quality.

Another object of the present invention is to provide a method for producing a chalcopyrite-type solar cell with reduced production costs.

According to an aspect of the present invention, there is provided a method for producing a chalcopyrite-type solar cell having at least a light absorbing layer containing a chalcopyrite-type compound, the light absorbing layer being interposed between first and second electrode layers, the electrode layers being formed on the upper side of a surface of a substrate. The method comprises the steps of forming a Cu—In—Ga alloy layer on the first electrode layer by sputtering using a Cu—In—Ga alloy target, and subjecting the Cu—In—Ga alloy layer to a selenization treatment, thereby converting the Cu—In—Ga alloy to the chalcopyrite-type compound to obtain the light absorbing layer.

In the present invention, the Cu—In—Ga alloy target (the CIG target) is used for forming the alloy layer that has approximately the same composition as the Cu—In—Ga alloy target. In the alloy layer, particles of elements of Cu, In, and Ga are substantially uniformly dispersed. In other words, in the alloy layer, the particles of Cu, In, and Ga are substantially uniformly mixed.

Thus, the selective reaction of Ga and Se is hardly caused in the selenization treatment of the alloy layer, so that Ga segregation in the lower portion of the light absorbing layer is efficiently prevented. As a result, the formation of the CuGaSe₂ layer (i.e. the separation of the light absorbing layer) can be prevented, and the resultant light absorbing layer can have a substantially uniform single-layer Cu(In,Ga)Se structure.

In other words, when the Cu—In—Ga alloy target is used to form the alloy layer having substantially the same composition as the target, and the alloy layer is converted to the light absorbing layer containing the chalcopyrite-type compound by the selenization treatment, the obtained light absorbing layer can be free from the CuGaSe₂ layer.

The chalcopyrite-type solar cell having the approximately uniform single light absorbing layer has fewer interface defects and is more excellent in properties such as current-voltage characteristics and quantum efficiency, as compared with the above described solar cells having the separate bilayer structure. Thus, the chalcopyrite-type solar cell produced by the method of the present invention has excellent power generation properties.

Furthermore, in the present invention, only one film formation step is required, and the complicated processes (such as a target replacement process for stacking three or two layers to prepare the precursor) are not required. Therefore, the chalcopyrite-type solar cell can be produced in a shorter time without the replacement process, with a remarkably improved production efficiency.

The CIG target has a low resistance, and thus, the layer can be formed by DC sputtering or the like. In the case of using the DC sputtering, the film formation speed can be increased, whereby the chalcopyrite-type solar cell can be produced more efficiently.

To obtain the light absorbing layer with an ideal Cu—In—Ga composition, the Cu—In—Ga alloy target preferably has a Cu—In—Ga composition satisfying a predetermined condition. Specifically, it is preferred that the target have a Cu—In—Ga composition satisfying both the following inequalities (1) and (2).

0.7≦Cu/(In+Ga)≦0.99 (1)

0.4≦Ga/(In+Ga)≦0.7 (2)

The above and other objects, features, and advantages of the present invention will become more apparent from the following description when taken in conjunction with the accompanying drawings in which a preferred embodiment of the present invention is shown by way of illustrative example.

### BRIEF DESCRIPTION OF THE DRAWINGS

FIG. 1 is a schematic side view showing a chalcopyrite-type solar cell according to an embodiment of the present invention;

FIG. 2 is an explanatory view showing formation of a Cu—In—Ga alloy layer by sputtering using a Cu—In—Ga alloy target;

FIG. 3 is a schematic side view showing the alloy layer formed on a first electrode layer;

FIG. 4 is a schematic side view showing a light absorbing layer containing a chalcopyrite-type compound converted from the alloy layer by a selenization treatment;

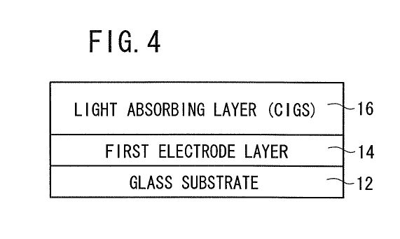

FIG. 5 is a chart showing X-ray diffraction patterns of the light absorbing layer formed by a method according to the present embodiment and a light absorbing layer formed by a conventional technology in a low angle region;

FIG. 6 is a chart showing X-ray diffraction patterns of the light absorbing layer formed by the method according to the present embodiment and the light absorbing layer formed by the conventional technology in a high angle region;

FIG. 7 is a graph showing current-voltage characteristics of a solar cell battery having the light absorbing layer formed by the method according to the present embodiment and a solar cell battery having the light absorbing layer formed by the conventional technology;

FIG. 8 is a graph showing the quantum efficiencies of the solar cell battery having the light absorbing layer formed by the method according to the present embodiment and the solar cell battery having the light absorbing layer formed by the conventional technology;

FIG. 9 is a schematic side view showing a Cu layer, an In layer, and a Ga layer formed on a first electrode layer by multi-sputtering Cu, In, and Ga targets; and

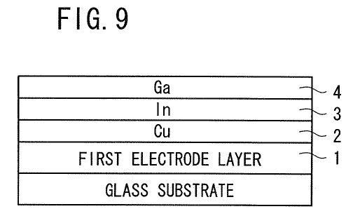

FIG. 10 is a schematic side view showing a lower CuGaSe₂ layer and an upper Cu(In,Ga)Se layer in a light absorbing layer formed by selenizing the Cu layer, the In layer, and the Ga layer of FIG. 9.

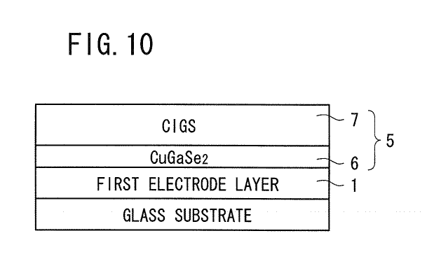

### DESCRIPTION OF THE PREFERRED EMBODIMENTS

A preferred embodiment of the chalcopyrite-type solar cell production method of the present invention will be described in detail below with reference to the attached drawings.

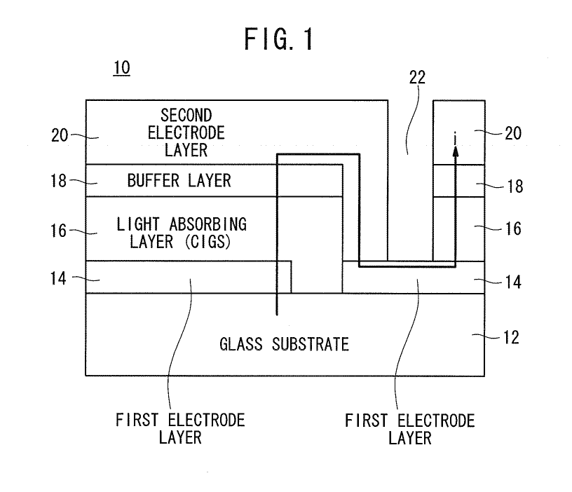

First, a structure of a chalcopyrite-type solar cell will be described below with reference to FIG. 1 schematically showing the solar cell. The chalcopyrite-type solar cell 10 has a first electrode layer 14, a light absorbing layer 16 comprising a p-type semiconductor of a chalcopyrite-type compound, a buffer layer 18 comprising an n-type semiconductor, and a transparent second electrode layer 20 stacked in this order on a glass substrate 12.

The first electrode layer 14 is generally made of a metal, and preferred materials therefor include Mo, W, etc.

In this embodiment, the light absorbing layer 16 formed on the first electrode layer 14 is made of Cu(In,Ga)Se (so-called CIGS). As described hereinafter, the light absorbing layer 16 is formed by selenizing a precursor, i.e., a Cu—In—Ga alloy layer.

Preferred materials for the buffer layer 18 disposed on the light absorbing layer 16 include CdS, ZnS, InS, etc. The second electrode layer 20 comprises a transparent material having a high power collection efficiency and an excellent light transmittance suitable for transmitting a light such as a solar light. Preferred examples of such transparent materials include ZnO doped with Al (ZnO—Al), etc.

In FIG. 1, the reference number 22 represents a scribed groove formed by scribing in the production of the chalcopyrite-type solar cell 10.

In the chalcopyrite-type solar cell 10 having such a structure, a photocurrent i flows along an arrow shown in FIG. 1.

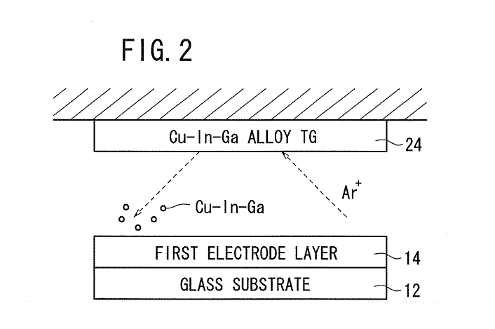

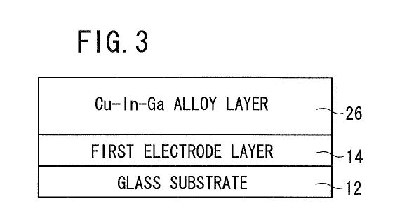

Then, a method for producing the chalcopyrite-type solar cell 10 according to the present embodiment will be described below. The production method comprises the steps of forming a Cu—In—Ga alloy layer 26 (a precursor of the light absorbing layer 16, see FIG. 3) on the first electrode layer 14 by using a Cu—In—Ga alloy target 24 (see FIG. 2), and selenizing the Cu—In—Ga alloy layer 26 to form the light absorbing layer 16 containing the CIGS. The Cu—In—Ga alloy layer 26 and the Cu—In—Ga alloy target 24 may be hereinafter referred to simply as the alloy layer 26 and the CIG target 24 respectively.

First, the first electrode layer 14 made of Mo, W, or the like is formed on the glass substrate 12, for example, by sputtering.

Next, the alloy layer 26 (the precursor of the light absorbing layer 16) is formed on the first electrode layer 14. This formation is achieved by sputtering using the CIG target 24 as shown in FIG. 2. The CIG target 24 has a low resistance, and thus can be sputtered by DC sputtering, which has a high film formation speed.

In this embodiment, the CIG target 24 has a Cu—In—Ga composition satisfying both the following inequalities (1) and (2).

0.7≦Cu/(In+Ga)≦0.99 (1)

0.4≦Ga/(In+Ga)≦0.7 (2)

In the case of using the CIG target 24 having such a composition, the light absorbing layer 16 can have a Ga composition ratio near the ideal value of 0.6.

In the sputtering, for example, ionized Ar collides against the CIG target 24 at high speed, and atoms or molecules of the Cu—In—Ga alloy are released from the CIG target 24. The released atoms or molecules are attached to and deposited on the first electrode layer 14 to form the alloy layer 26 having a predetermined thickness.

As is clear from the above, in this embodiment, the sputtering is carried out only once using the CIG target 24 composed of the ternary Cu—In—Ga alloy to form the Cu—In—Ga alloy layer 26. Thus, the alloy layer 26 can be formed in a significantly shorter time in the present embodiment than in the conventional technologies, which contain multiple sputtering using Cu, In, and Ga targets or Cu and In—Ga targets.

In the conventional technologies, complicated processes of opening a chamber of sputtering equipment and replacing the target are required in order to stack the layers of different materials. In contrast, in the present embodiment, the sputtering is carried out only once, whereby the production procedures can be simplified.

For the above reasons, in this embodiment, the time required to produce the chalcopyrite-type solar cell 10 can be shortened, and the production efficiency can be improved. For example, the number of the solar cells 10, produced in a unit time can be increased two- to three-fold.

In this embodiment, the CIG target 24 has the above-mentioned composition, and particles of Cu, In, and Ga are substantially uniformly dispersed in the formed alloy layer 26.

It is preferred that an alkali layer (not shown) be formed on the alloy layer 26. For example, the alkali layer may be formed by applying an aqueous solution containing alkali metals such as an aqueous sodium salt solution (e.g. an aqueous sodium chloride solution) to the alloy layer 26 and thereafter drying the applied solution. The solution may be applied by immersing a partially-processed product having the alloy layer 26 in the solution. Alternatively, the solution may be applied by a known application method such as a spin coating method.

The partially-processed product on which the alkali layer is formed, is placed in a heat treatment furnace and subjected to a preheating, and then a selenization gas such as H₂Se gas is introduced into the heat treatment furnace. The Cu—In—Ga alloy of the alloy layer 26 is selenized and converted to the chalcopyrite-type compound Cu(In,Ga)Se by the selenization gas, so that the light absorbing layer 16 is formed.

In this step, the crystallization of the Cu(In,Ga)Se is accelerated by an alkali component such as Na contained in the alkali layer. The alkali layer is diffused in the light absorbing layer 16 and finally disappears. Thus, the alkali layer does not remain as a layer on the light absorbing layer 16.

As described above, the Cu, In, and Ga particles contained in the alloy layer 26 are dispersed in a substantially uniformly mixed state. Therefore, the selective reaction of Ga and Se is hardly caused in the selenization of the alloy layer 26, so that the formation of a CuGaSe₂ layer due to the Ga segregation in the lower portion of the light absorbing layer 16 on the first electrode layer 14 is prevented. As a result, the light absorbing layer 16 has a uniform single-layer Cu(In,Ga)Se structure.

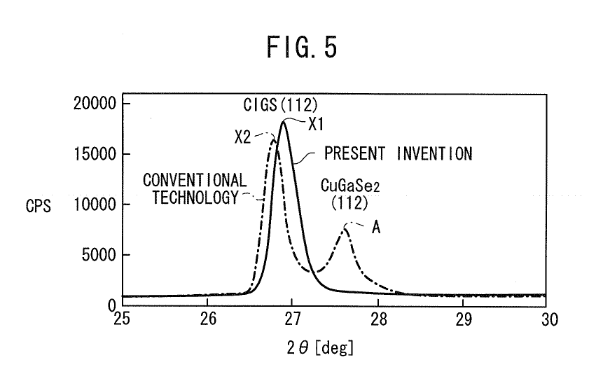

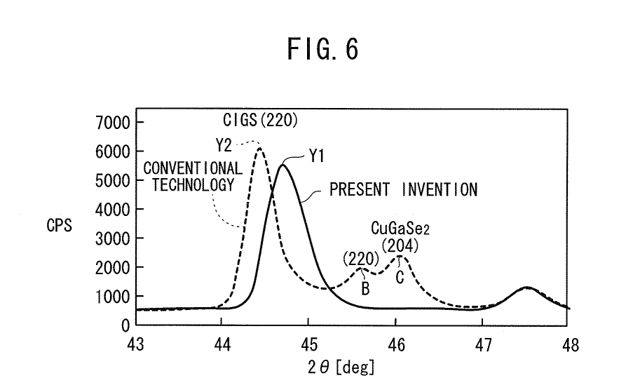

The above can be confirmed by measured X-ray diffraction patterns of FIGS. 5 and 6. FIGS. 5 and 6 show the X-ray diffraction patterns of a light absorbing layer formed by a conventional technology containing the steps of stacking a Cu layer, an In layer, and a Ga layer on the first electrode layer 14 and thereafter selenizing the stacked layers and the light absorbing layer 16 formed by the method of the present embodiment containing the steps of forming the alloy layer 26 using the CIG target 24 composed of the Cu—In—Ga alloy and thereafter selenizing the alloy layer 26. The patterns in a low angle region are shown in FIG. 5, and the patterns in a high angle region are shown in FIG. 6.

As shown in FIGS. 5 and 6, the X-ray diffraction patterns of the light absorbing layer formed by the conventional technology have clear peaks A, B, and C resulting from the CuGaSe₂. In contrast, the patterns of the light absorbing layer 16 formed in the present embodiment have no peaks resulting from the CuGaSe₂. It is clear from the above results that the light absorbing layer 16 does not have the CuGaSe₂ layer. In other words, the light absorbing layer 16 is formed as a uniform single CIGS layer without the layer separation.

Furthermore, the CIGS peaks X2 (FIG. 5) and Y2 (FIG. 6) of the light absorbing layer formed by the conventional technology are observed at lower angles than the CIGS peaks X1 (FIG. 5) and Y1 (FIG. 6) of the light absorbing layer 16. This means that the CIGS in the light absorbing layer formed by the conventional technology has a low Ga composition ratio.

Thus, the light absorbing layer 16 that has the uniform single-layer structure without the layer separation and has the ideal Ga concentration, can be obtained by forming the alloy layer 26 using the CIG target 24 composed of the Cu—In—Ga alloy and thereafter selenizing the alloy layer 26.

Next, the buffer layer 18 made of an n-type semiconductor such as CdS, ZnS, InS, etc. is formed by a chemical bath deposition method, etc.

Then, a mechanical scribing is carried out, and the second electrode layer 20 is formed. For example, a transparent ZnO—Al layer is formed as the second electrode layer 20 by sputtering using a ZnO—Al target.

Thereafter, the mechanical scribing is carried out again, thereby dividing into a predetermined number of cells, whereby a solar cell battery including the chalcopyrite-type solar cells 10 is obtained.

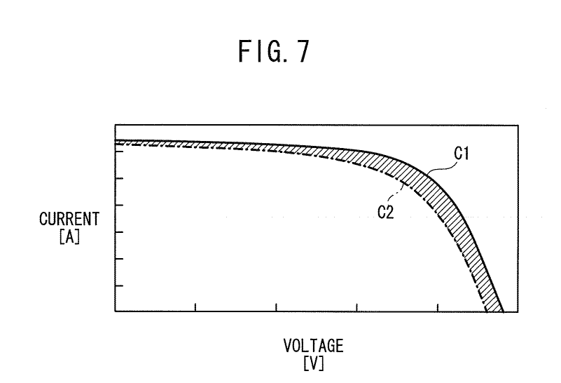

FIG. 7 is a graph showing current-voltage characteristics (I-V characteristics) of the solar cell battery obtained by the method of the present embodiment and a solar cell battery obtained by the above conventional technology. The curve C1 is the I-V characteristic curve of the solar cell battery obtained by the method of the present embodiment, and the curve C2 is the I-V characteristic curve of the solar cell battery obtained by the conventional technology.

It is clear from FIG. 7 that the solar cell battery obtained by the method of the present embodiment shows a higher voltage under an identical current, and thus has a higher power output. The power output is increased by approximately 10% to 20%, which is calculated from the area of the region surrounded by the curve C1 and the curve C2 (i.e. the region shown by diagonal lines in FIG. 7).

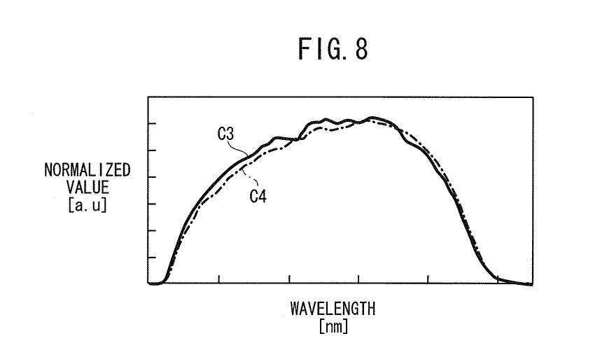

FIG. 8 is a graph showing the quantum efficiencies of the solar cell battery obtained by the method of the present embodiment (curve C3) and the solar cell battery obtained by the conventional technology (curve C4), representing the relationship between wavelength and normalized value. In FIG. 8, the normalized value of the curve C3 is larger than that of the curve C4 in a region between a low wavelength and a visible light wavelength. Thus, it is confirmed that the quantum efficiency can be increased in this wavelength region by using the production method containing the steps of forming the alloy layer 26 using the Cu—In—Ga alloy target 24 and thereafter selenizing the alloy layer 26.

In the present embodiment, the quantum efficiency is improved in this manner, whereby the short-circuit current is increased. Furthermore, internal defects of the chalcopyrite-type solar cell 10 are reduced, so that the open circuit voltage is advantageously increased.

Thus, in the present embodiment, the chalcopyrite-type solar cell 10 which is excellent in various properties, is obtained.

Though the CIG target 24 has the Ga composition satisfying both the inequalities (1) and (2) in the above embodiment, the CIG target 24 may have any composition as long as the selenized alloy layer 26 can act as the light absorbing layer.

In addition, the CIG target 24 may be sputtered by a method other than the DC sputtering.

While the invention has been particularly shown and described with reference to the preferred embodiments, it will be understood that variations and modifications can be effected thereto by those skilled in the art without departing from the spirit of the invention as defined by the appended claims.

What is claimed is:

1. A method for producing a chalcopyrite-type solar cell having at least a light absorbing layer containing a chalcopyrite-type compound, the light absorbing layer being interposed between a first electrode layer and a second electrode layer, the electrode layers being formed on an upper side of a surface of a substrate, comprising the steps of
forming a Cu—In—Ga alloy layer on the first electrode layer by sputtering using a Cu—In—Ga alloy target, and
subjecting the Cu—In—Ga alloy layer to a selenization treatment, thereby converting the Cu—In—Ga alloy to the chalcopyrite-type compound to obtain the light absorbing layer.

2. A method according to claim 1, wherein the Cu—In—Ga alloy target has a Cu—In—Ga composition satisfying both the following inequalities (1) and (2):
0.7≦Cu/(In+Ga)≦0.99 (1)
0.4≦Ga/(In+Ga)≦0.7 (2).

3. A method according to claim 1, wherein the sputtering using the Cu—In—Ga alloy target is DC sputtering.

4. A method according to claim 1, wherein an alkali layer is formed on the Cu—In—Ga alloy layer before the step of subjecting the Cu—In—Ga alloy layer to the selenization treatment.

5. A method according to claim 4, wherein the alkali layer is formed by applying an aqueous solution containing alkali metals onto the Cu—In—Ga alloy layer and thereafter drying the applied solution.

6. A method according to claim 5, wherein the alkali layer is formed by immersing a partially-processed product having the Cu—In—Ga alloy layer in the aqueous solution containing alkali metals and thereafter drying the applied solution.

7. A method according to claim 5, wherein the alkali layer contains Na.
